(19) United States
(12) Patent Application Publication
(10) Pub. No.: US 2026/0252150 A1
(43) Pub. Date: Aug. 27, 2026

(54) HIGH-DENSITY PACKAGING OF APPLICATION-SPECIFIC INTEGRATED CIRCUITS IN A DILUTION REFRIDGERATOR

(71) Applicant: International Business Machines Corporation, Armonk, NY (US)

(72) Inventors: Devin Underwood, Bronx, NY (US); Shawn Anthony Hall, Pleasantville, NY (US); Trevor Timpane, Rochester, MN (US); Christian Wilhelmus Baks, Pleasant Valley, NY (US); David James Frank, Yorktown Heights, NY (US); Michael Boraas, Zumbrota, MN (US); Brian Paul Gaucher, Brookfield, CT (US)

(21) Appl. No.: 19/061,340

(22) Filed: Feb. 24, 2025

(51) Int. Cl. G06F 1/20; H05K 7/20

(52) U.S. Cl. CPC G06F 1/20; H05K 7/20254; H05K 7/2039

(57) ABSTRACT

Systems and techniques that facilitate high-density packaging of application-specific integrated circuits in a dilution refrigerator for quantum computing are provided. In an embodiment, a structure can comprise a backplane assembly, wherein the backplane assembly can comprise an internal backplane wiring that conveys, via a hub chip, a set of input signals from an input cable to a set of backplane connectors. The structure can comprise a set of daughter-card assemblies. The set of daughter-card assemblies can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

### BACKGROUND

The subject disclosure relates to quantum computing, and more specifically high-density packaging of complementary metal-oxide-semiconductor (CMOS) application-specific integrated circuits (ASICs) in a dilution refrigerator for quantum computing.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, devices and/or methods that facilitate high-density packaging of application-specific integrated circuits (ASICs) in a dilution refrigerator that facilitate scalable quantum computing are described.

According to an embodiment, a structure can comprise a backplane assembly, wherein the backplane assembly can comprise an internal backplane wiring that conveys, via a hub chip, a set of input signals from an input cable to a set of backplane connectors. The structure can further comprise a set of daughter-card assemblies. The set of daughter-card assemblies can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

According to another embodiment, a structure can comprise a backplane assembly, wherein the backplane assembly can comprise an internal backplane wiring that separately conveys a set of input signals from a set of input cables to a set of backplane connectors. The structure can further comprise a set of daughter-card assemblies. The set of daughter-card assemblies can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

According to another embodiment, a structure can comprise a cryogenic control assembly (CCA) that is positioned inside a dilution refrigerator, wherein the CCA is thermally anchored to a second stage of a pulse tube, or to a liquid helium circulation circuit. The CCA can comprise a backplane assembly that conveys a set of input signals from one or more input cables to a set of backplane connectors. The CCA can further comprise a set of cryogenic control units (CCUs). The set of CCUs can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

### DESCRIPTION OF THE DRAWINGS

FIG. 1 illustrates a block diagram of a cryogenic control assembly with a hub chip assembly in accordance with one or more embodiments described herein.

FIG. 2 illustrates a block diagram of a cryogenic control assembly without a hub chip assembly in accordance with one or more embodiments described herein.

FIG. 3 illustrates a front view of a cryogenic system with a cryogenic control assembly in accordance with one or more embodiments described herein.

FIG. 4 illustrates an exploded view of a cryogenic control unit and a backplane assembly in accordance with one or more embodiments described herein.

FIG. 5 illustrates an artificially exploded view of a cryogenic control assembly with a hub chip assembly in accordance with one or more embodiments described herein.

FIG. 6 illustrates an assembled cryogenic control assembly with a hub chip assembly in accordance with one or more embodiments described herein.

FIG. 7 illustrates a front view of a backplane assembly with a hub chip assembly in accordance with one or more embodiments described herein.

FIG. 8 illustrates a rear view of a backplane assembly with a hub chip assembly in accordance with one or more embodiments described herein.

FIG. 9 illustrates a front view of a cold plate assembly with a heat sink assembly in accordance with one or more embodiments described herein.

FIG. 10 illustrates a rear view of a cold plate assembly with a heat sink assembly in accordance with one or more embodiments described herein.

FIG. 11 illustrates an artificially exploded view of a field-replaceable unit in accordance with one or more embodiments described herein.

FIG. 12 illustrates an assembled field-replaceable unit in accordance with one or more embodiments described herein.

FIG. 13 illustrates a perspective cutaway view of a cryogenic control assembly with a hub chip assembly in accordance with one or more embodiments described herein.

FIG. 14 illustrates a side cutaway view of a cryogenic control assembly with a hub chip assembly in accordance with one or more embodiments described herein.

FIG. 15 illustrates a magnified side cutaway view of a cryogenic control assembly with a hub chip assembly in accordance with one or more embodiments described herein.

FIG. 16 illustrates an artificially exploded view of a cryogenic control assembly without a hub chip assembly in accordance with one or more embodiments described herein.

FIG. 17 illustrates a front view of a backplane assembly without a hub chip assembly in accordance with one or more embodiments described herein.

FIG. 18 illustrates a rear view of a backplane assembly without a hub chip assembly in accordance with one or more embodiments described herein.

FIG. 19 illustrates a front view of a cold plate assembly without a hub chip assembly in accordance with one or more embodiments described herein.

FIG. 20 illustrates a rear view of a cold plate assembly without a hub chip assembly in accordance with one or more embodiments described herein.

FIG. 21 illustrates an array of fully populated cryogenic control packages with a set of field-replaceable units in accordance with one or more embodiments described herein.

FIG. 22 illustrates a block diagram of wiring of a cryogenic control assembly with a hub chip assembly in accordance with one or more embodiments described herein.

FIG. 23 illustrates a block diagram of wiring of a cryogenic control assembly without a hub chip assembly in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

According to an embodiment, a structure can comprise a backplane assembly, wherein the backplane assembly can comprise an internal backplane wiring that conveys, via a hub chip, a set of input signals from an input cable to a set of backplane connectors. The structure can further comprise a set of daughter-card assemblies. The set of daughter-card assemblies can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

Advantages of such a structure is that it can reduce packaging size of control electronics for improved scalability by enabling high-density packaging, enable modular serviceability, enhance signal integrity by generating the input signals at a low temperature compared to generating the input signals at room temperature, and improved thermalization without overheating a dilution refrigerator. A further advantage of the hub chip is that it can reduce the packaging size of control electronics by reducing wiring complexity, such as reducing the number of input signal lines going into the dilution refrigerator, and thus can improve scalability as the size of the quantum processor increases due to the reduced packaging size.

In one or more embodiments of the aforementioned structure, one or more of the set of daughter-card assemblies can comprise a heat-spreader that is in thermal contact with the set of processing chips and with a high-thermal-conductivity backplate, wherein the high-thermal-conductivity backplate is in thermal contact with a refrigerated plate that is held at the first cryogenic temperature.

An advantage of such a structure is that it can enhance heat transfer efficiency, enabling uniform cooling and stable operation at cryogenic temperatures.

In one or more embodiments of the aforementioned structure, each of the set of daughter-card assemblies can comprise a daughter card that is a U-shape, wherein the daughter card comprises a base and two legs. In one or more embodiments of the aforementioned structure, the set of daughter-card assemblies can comprise a set of receptacles for electrical connection to a subset of the set of backplane connectors, wherein the set of receptacles are electrically connected to a distal end of each of the two legs, wherein the set of processing chips are electrically connected to a proximal end of each of the two legs, and wherein the set of output cables are electrically connected to the set of quantum processors at the second cryogenic temperature.

An advantage of such a structure is that it can improve serviceability by enabling independent removal of a daughter-card assembly without removing any of the set of output cables.

In one or more embodiments of the aforementioned structure, the set of output cables can be routed through an open area of the U-shape such that any of the set of daughter-card assemblies are capable of being separately removed without removing any other of the set of daughter-card assemblies, and such that any of the set of daughter-card assemblies are capable of being separately removed without removing any of the set of output cables.

An advantage of such a structure is that it can improve serviceability by enabling independent removal of a daughter-card assembly from anywhere in an array of daughter-card assemblies when repair or replacement is needed.

In one or more embodiments of the aforementioned structure, each of the set of daughter-card assemblies can comprise a daughter card that is rectangular, wherein the set of output cables extend off a front of the set of daughter-card assemblies, and wherein a top daughter-card assembly of the set of daughter-card assemblies is capable of being independently removed.

An advantage of such a structure is that it can improve serviceability by enabling independent removal of a daughter-card assembly from a top of an array of daughter-card assemblies when repair or replacement is needed.

In one or more embodiments of the aforementioned structure, the structure can further comprise a cold plate assembly, wherein the cold plate assembly can comprise a left cold plate and a right cold plate that affix to the refrigerated plate.

An advantage of such a structure is that it can enhance thermal conduction, enabling efficient cooling of components across the structure.

In one or more embodiments of the aforementioned structure, the structure can further comprise a heat sink assembly, wherein the heat sink assembly can comprise a first cold block that is affixed to the hub chip, a second cold block that is affixed to the left cold plate, and a third cold block that is affixed to the right cold plate, wherein the first cold block, the second cold block, and the third cold block are connected by a thermally affixed conductive rope.

An advantage of such a structure is that it can improve heat dissipation while still enabling high-density packaging.

In one or more embodiments of the aforementioned structure, the heat-spreader can comprise a set of handles.

An advantage of such a structure is that the CCUs can be more easily serviced by enabling easier removal of the CCUs for repair or replacement.

According to another embodiment, a structure can comprise a backplane assembly, wherein the backplane assembly can comprise an internal backplane wiring that separately conveys a set of input signals from a set of input cables to a set of backplane connectors. The structure can further comprise a set of daughter-card assemblies. The set of daughter-card assemblies can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

Advantages of such a structure is that it can reduce packaging size of control electronics for improved scalability by enabling high-density packaging, enable modular serviceability, enhance signal integrity by generating the input signals at a low temperature compared to generating the input signals at room temperature, and improved thermalization without overheating a dilution refrigerator. A further advantage of such a structure is that it can simplify development of the structure due to the absence of the hub chip and can also avoid the power consumption of the hub chip. A further advantage of the structure is that the backplane is passive, which is easier to build or develop.

According to another embodiment, a structure can comprise a cryogenic control assembly (CCA) that is positioned inside a dilution refrigerator, wherein the CCA is thermally anchored to a second stage of a pulse tube, or to a liquid helium circulation circuit. The CCA can comprise a backplane assembly that conveys a set of input signals from one or more input cables to a set of backplane connectors. The CCA can further comprise a set of cryogenic control units (CCUs). The set of CCUs can comprise a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

Advantages of such a structure is that it can reduce packaging size of control electronics for improved scalability by enabling high-density packaging, enable modular serviceability, enhance signal integrity by generating the input signals at a low temperature compared to generating the input signals at room temperature, and improved thermalization without overheating a dilution refrigerator.

In one or more embodiments of the aforementioned structure, the structure can further comprise a hub chip assembly that can multiplex the set of input signals to the set of CCUs.

Advantages of such a structure is that it can reduce the packaging size of control electronics by reducing wiring complexity, such as reducing the number of input signal lines going into the dilution refrigerator, and thus can improve scalability as the size of the quantum processor increases due to the reduced packaging size.

In one or more embodiments of the aforementioned structure, the set of CCUs can be thermally anchored to the second stage of the pulse tube or to the liquid helium circulation circuit.

An advantage of such a structure is that it can enhance thermal management, ensuring stable operations at cryogenic temperatures.

In one or more embodiments of the aforementioned structure, the one or more input cables can be high-density ribbon cables.

An advantage of such a structure is that high-density ribbon cables can increase signal routing capacity in compact form, enabling efficient connections.

In one or more embodiments of the aforementioned structure, the set of processing chips can form multi-chip modules on a daughtercard.

An advantage of such a structure is that it can improve scalability by allowing for integration of multiple processing chips while reducing space and interconnection complexity.

Variations of one or more embodiments are also envisioned.

To achieve efficient operation in quantum systems, cryogenic control electronics should at scale be modular, easily serviceable, high density, and thermalized without overheating the dilution refrigerator. Historically, quantum computers comprising superconducting qubits have been small enough that all N qubits and supporting equipment fit in a single existing cryostat. However, because N continually grows as quantum technology progresses, the number of qubits is now so large that a single monolithic refrigerator can no longer accommodate all of them. As N continues to grow, building ever-larger dilution refrigerators utilizing existing designs grows increasingly expensive, and leads to hardware sizes that are ultimately untenable, cumbersome, and unmanageable. Accordingly, when N exceeds the number of qubits that can be packaged together, a number that depends on engineering limits of qubit-supporting infrastructure (e.g., chips, circuit-boards, connectors, cabling, and cooling equipment), then the N qubits are divided into a plurality of groups called payloads. Yet, for a quantum computer to be effective, payloads must be able to send electromagnetic signals to their neighbors over quantum-link cables that are as short as possible, and which remain superconducting over their entire length to minimize loss.

However, it is difficult to scale cryogenic control electronics for such quantities of qubits per dilution refrigerator due to volume constraints within the cryostat. Further, scaling of the cryogenic control electronics is restricted by cooling limitations set by pulse tubes or liquid-cryogen cooling circuits. That is, as the size of the quantum processor increases, the more control electronics that are needed, which can be challenging to fit within the thermal and spatial constraints of the dilution refrigerator.

Consequently, to enable quantum computers in which N is large, it is desirable to repackage control electronics in a manner that eliminates the problems just described. For example, some large quantum systems target between 1k or 3k qubits per dilution refrigerator. Scaling to such large number of qubits is challenging for existing packaging infrastructures of control electronics, as they cannot fit within the spatial limitations of the dilution refrigerator or adhere to the thermal limitations (e.g., cooling limitations set by pulse tubes or liquid-cryogen cooling circuits) and can thus overheat the dilution refrigerator. It is also desirable for the repackaged control electronics to be modular and easily serviceable to facilitate repairs and replacements.

In one or more embodiments described herein, systems, devices and/or method that facilitate high-density packaging of ASICs in a dilution refrigerator for quantum computing are described that address the above-described problems with existing cryogenic control electronics. In one or more embodiments described herein, a structure can comprise a backplane assembly, wherein the backplane assembly comprises: an internal backplane wiring that conveys a set of input signals from an input cable to a set of backplane connectors. In one or more embodiments described herein, the structure can further comprise a set of daughter-card assemblies, wherein the set of daughter-card assemblies comprises: a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature. Accordingly, the high-density structure of the daughter-card assemblies enables scalability of quantum computing as more daughter-card assemblies can be fit into a dilution refrigerator to handle more qubits of a quantum processor while adhering to thermal limitations of the dilution refrigerator. Furthermore, in one or more embodiments described herein, the structure enables easy serviceability by allowing any of an array of daughter-card assemblies to be removed independently. That is, a daughter-card assembly can be removed without removing other daughter-card assemblies or output cables.

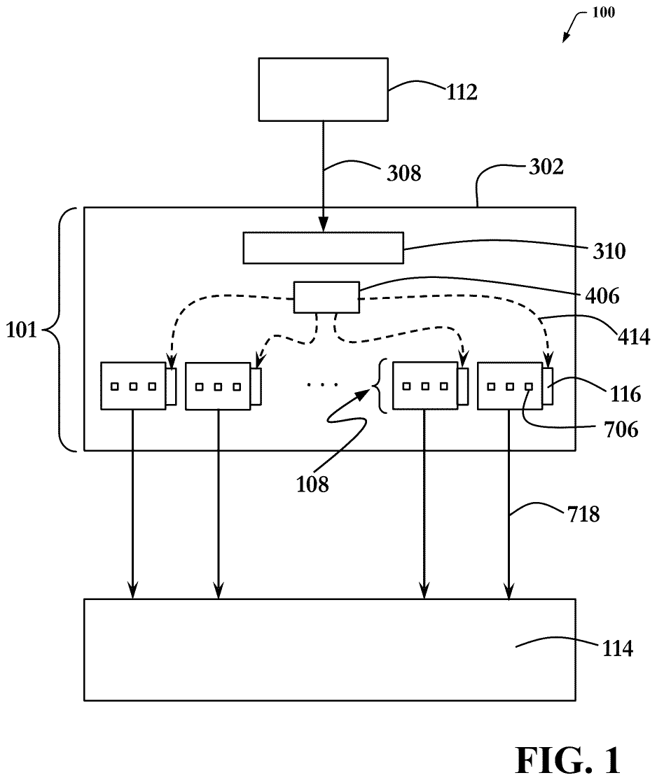

Accordingly, a block diagram of a first embodiment 100 is illustrated by FIG. 1. In various aspects, first embodiment 100 can comprise a cryogenic control assembly (CCA) 101. In CCA 101, a plurality of signals generated by room-temperature electronics (RTE) 112, henceforth called “RTE signals”, can be routed on one or more input cable 308 to a backplane 302 via at least one input connector 310. Backplane 302 can be held at a first cryogenic temperature T₁. Thereafter, the plurality of RTE signals can be distributed as a set of input signals 414 via a hub-chip 406 to a set of cryogenic control units (CCUs) 108. The set of CCUs 108 can comprise an integer number N of CCUs. Each of the set of CCUs 108 can be electrically connected to backplane 302 via one or more backplane connectors 304. Each of the set of CCUs 108 can comprise qubit control electronics. Particularly, each of the set of CCUs 108 can comprise a plurality of daughter-card assemblies 702, such as qubit control ASICs, each of which can comprise a digital processor and a plurality of analog waveform generators.

Within each of the plurality of daughter-card assemblies 702, the digital processor can interpret the set of input signals 414. Accordingly, the digital processor within each of the plurality of daughter-card assemblies 702 can produce therefrom a set of output signals on a set of output cables 718. In various aspects, the set of output signals can be quantum-processor-unit (QPU) control signals that the set of output cables 718 can convey to a QPU 114. For example, the plurality of daughter-card assemblies 702 can be radio frequency (RF) ASICs that produce control pulses such as single-qubit X/Y rotations. As another example, the plurality of daughter-card assemblies 702 can be current-source ASICs that produce flux-based entanglement. In some instances, an RF ASIC and a flux ASIC can be fabricated onto a same daughter-card assembly.

In various cases, the set of output cables 718 can convey the set of output signals to one or more QPUs. In any case, the QPU 114 can be held at a second cryogenic temperature T₂.

In various aspects, CCA 101 further comprise thermally efficient means to cool the set of daughter-card assemblies 702 and other electronics in CCA 101. That is, CCA 101 can provide a heat-flow path from the set of daughter-card assemblies 702 to a refrigerated cold plate not shown (e.g., cooling plate 318) in which a temperature rise ΔT between the refrigerated cold plate and the set of daughter-card assemblies 702 is relatively small. The refrigerated cold plate can be refrigerated by a pulse-tube cooler or by a liquid-cryogen circulation. In various embodiments, a small temperature rise ΔT can be achieved by creating a short heat-flow path with high-thermal-conductivity material and with few thermal interfaces.

An advantage of CCA 101 is that backplane connectors 304 only convey the set of input signals 414. More specifically, the set of input signals 414 have less-stringent signal integrity requirements than the set of output signals (e.g., QPU control signals). Consequently, since backplane connectors 304 only convey less-stringent signals, backplane connectors 304 can be chosen from an abundance of low-cost and commercially available backplane connectors that are suitable for any geometry of application.

Another advantage of CCA 101, in comparison to alternative systems in which output signals are generated at room temperature, is that the set of output signals are generated at lower temperatures and can thus have a lower white-noise floor than room-temperature-generated signals. Further, because the set of output signals are generated at lower temperatures, CCA 101 can achieve improved signal integrity by eliminating lossy and dispersive elements from a signal path to QPU 114.

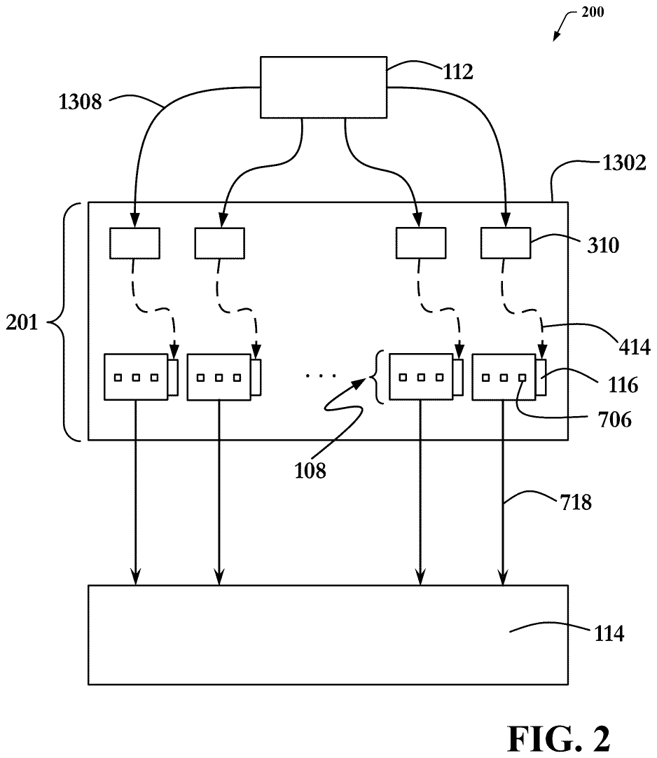

A block diagram of a second embodiment 200 is illustrated by FIG. 2. Second embodiment 200 is similar to first embodiment 100 except that hub-chip 406 is eliminated, resulting in CCA 201. More specifically, in CCA 201 of second embodiment 200, the set of input signals 414 for the set of CCUs 108 can be brought separately to CCA 201 on a set of input cables 1308, where the set of input cables 1308 can comprise N input cables rather than a single input cable 308 as in first embodiment 100. To separately convey the set of input signals 414 to the set of CCUs 108, CCA 201 can comprise a set of input connectors 310. That is, each of the plurality of RTE signals can be routed by a single input cable of the set of input cables 1308 to a backplane 1302 via a respective input connector 310. Conversely, CCA 101 can convey the plurality of RTE signals together, by a single input cable 308, to backplane 1302 via a single input connector 310, and thus to the set of CCUs 108 via a hub-chip 406.

An advantage of CCA 201 is that it does not require development of hub-chip 406 since hub-chip 406 is absent. Thus, CCA 201 reduces power consumption by avoiding the power consumption of hub-chip 406.

Alternatively, an advantage of CCA 101 is that the number of input cables 308 is reduced to one, thereby reducing system costs by eliminating component. Further, the reduction in the number of input cables 308 simplifies electrical routing of backplane 302, thereby facilitating a smaller packaging of cryogenic control electronics.

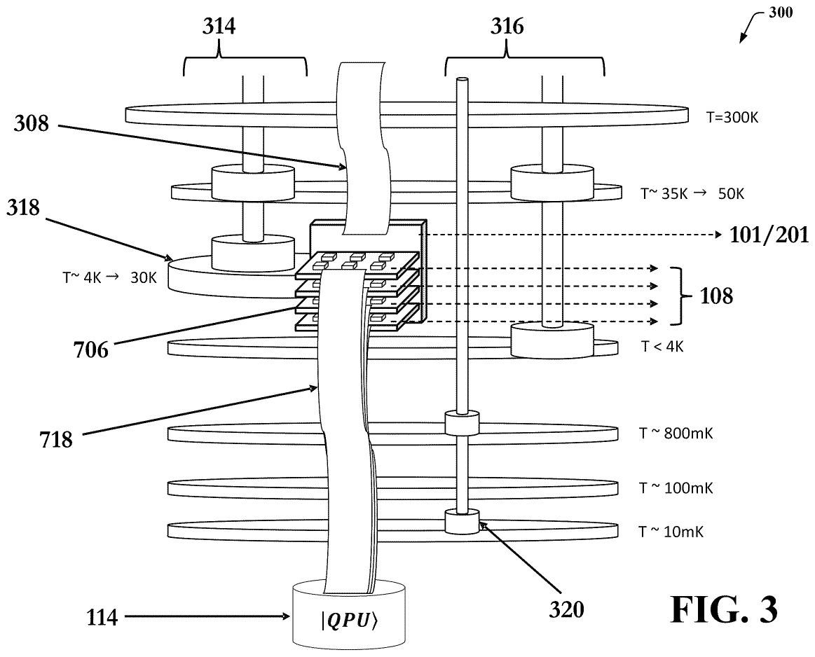

FIG. 3 illustrates a front view of a portion of a dilution refrigerator 300 comprising a CCA in accordance with one or more embodiments described herein. The dilution refrigerator 300 can comprise a plurality of temperature stages, ranging from room temperature, such as 300 K, to a base temperature, such as 10 mK, with various intermediate temperature stages. QPU 114 can be at a lowest temperature stage of the plurality of temperature stages (e.g., 10 mK).

The dilution refrigerator 300 can further comprise a cooling infrastructure 316 for QPU 114, consisting of a dilution unit 320. As depicted, the cryogenic control electronics of dilution refrigerator 300 can comprise CCA 101. The dilution refrigerator 300 can further comprise a cooling infrastructure for the cryogenic control electronics. The cooling infrastructure for the cryogenic control electronics can comprise cooling plate 318 for thermalizing the set of CCUs 108. Each of the set of CCUs 108 can comprise a set of processing chips 708. In various aspects, each of the set of CCUs 108 can comprise a daughter card (e.g., daughter card 702), to which the set of processing chips 708 are mounted. In such instances, the processing chips are often called daughter-card chips. Accordingly, as used herein, the term “processing chip” is used interchangeably with “daughter-card chip”. In various embodiments, the set of processing chips 708 can form multi-chip modules on the daughter card, where each multi-chip module is independent of one another. That is, processing within one module does not rely on or interfere with the processing in another module, enabling parallel operation and modular scalability.

Further, as discussed elsewhere in the present disclosure, the set of input signals 414 can be brought to the set of CCUs 108 on input cable 308 at the first cryogenic temperature T₁. Accordingly, the set of CCUs 108 can generate a set of output signals as functions of the set of input signals 414, and convey the set of output signals to QPU 114 at the second cryogenic temperature T₂ via the set of output cables 718.

Although dilution refrigerator 300 is depicted with cryogenic control electronics comprising CCA 101, dilution refrigerator 300 can also implement cryogenic control electronics comprising CCA 201. That is, alternatively, the set of input signals 414 be brought to the set of CCUs 108 on the set of input cables 1308.

Implementing CCA 101 or CCA 201 in dilution refrigerator 300 can provide a number of advantages, including improving serviceability, preventing overheating of dilution refrigerator 300, and providing high-density packaging of cryogenic control electronics that can fit between the plurality of temperature stages in dilution refrigerator 300. Additionally, by implementing CCA 101 or CCA 201 in dilution refrigerator 300, fridge input and output can be significantly reduced from room temperature down to the control package of the cryogenic control electronics. This can minimize thermal loads on dilution refrigerator 300 and enhance scalability for larger quantum systems.

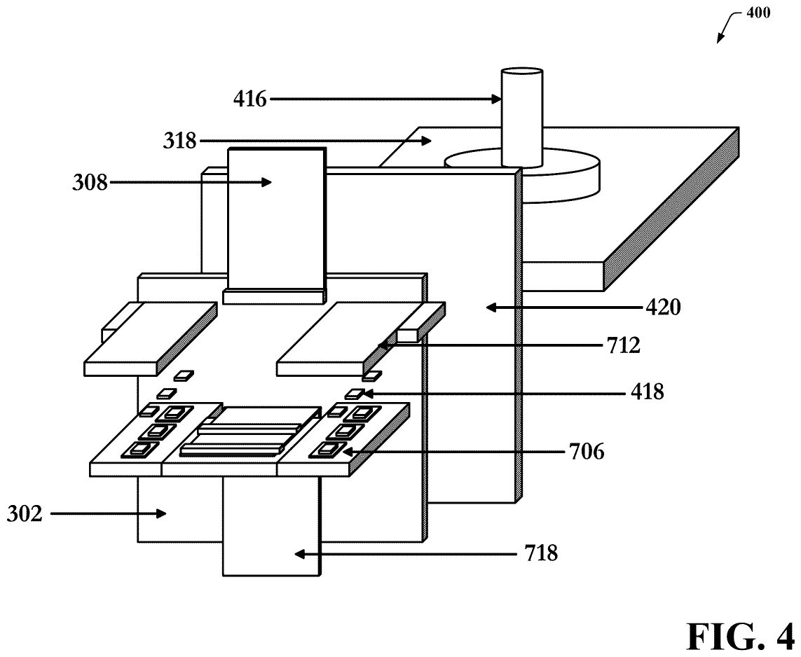

FIG. 4 illustrates an exploded view of a CCU of the set of CCUs 108 and a backplane assembly in accordance with one or more embodiments described herein.

The CCU can comprise an array of daughter card chip assemblies 706 (e.g., an array of ASICs 706). In various aspects, the array of daughter card chip assemblies 706 can comprise set of processing chips 708 (e.g., daughter-card chips 708), such as cryogenic complementary metal-oxide-semiconductor (CMOS) modules that are designed for operation at cryogenic temperatures. Accordingly, the plurality of RTE signals can be conveyed to backplane 302 on input cable 308 (e.g., or a set of input cables 1308), and thus to the CCU as the set of input signals 414 via backplane connectors 304 to support the cryogenic CMOS modules. The CCU can thereafter generate a set of output signals that can be conveyed to QPU 114 on the set of output cables 718.

The CCU can further comprise a heat spreader 712, and a set of thermal interface materials 418 that can thermally interface with the array of daughter card chip assemblies 706 and heat spreader 712. The backplane 302 can interface with a control assembly backing plate 420. The control assembly backing plate 420 can further interface with cooling plate 318 that can include a cooling reservoir 416. The cooling reservoir 416 can dissipate heat generated by the set of daughter card chip assemblies 706 to maintain cryogenic temperatures by facilitating heat transfer to dilution refrigerator 300.

Although FIG. 4 is depicted with CCA 101, the various embodiments can also apply to CCA 201. For example, backplane 1302 can interface with control assembly backing plate 420 which can interface with cooling plate 318.

Quantum systems inevitably suffer periodic failure of failure-prone components, recovery from which is preferably fast and efficient, thereby to minimize downtime of the system. As is well known, such fast recovery is often best achieved by replacing an entire failed module rather than debugging low-level hardware in the field. Such a replaceable module is often called a field-replaceable unit, or FRU. As used herein, the term “CCU” is used interchangeably with “FRU”.

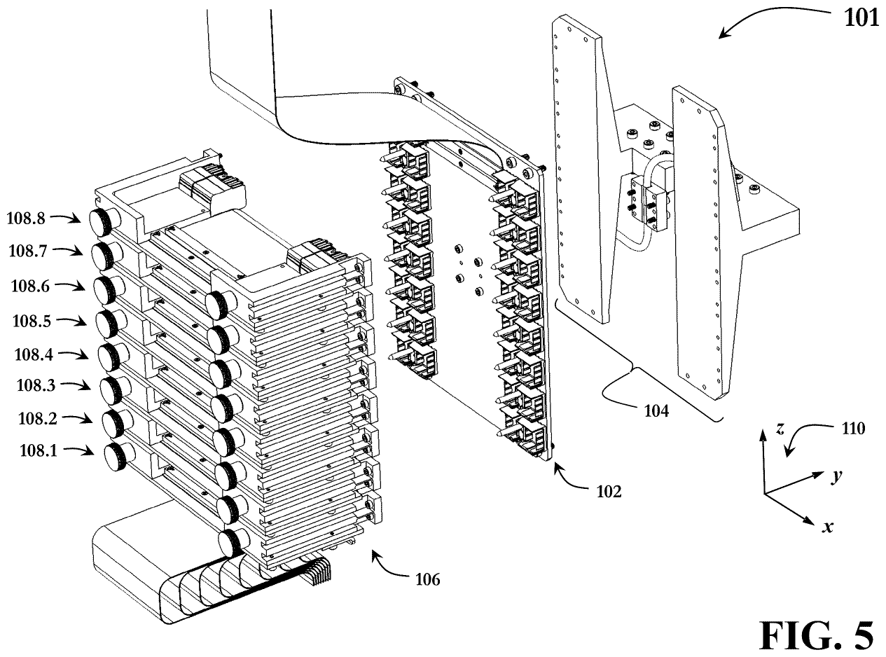

FIGS. 5-20 illustrate CCA 101 of first embodiment 100 and CCA 201 of second embodiment 200 in more detail.

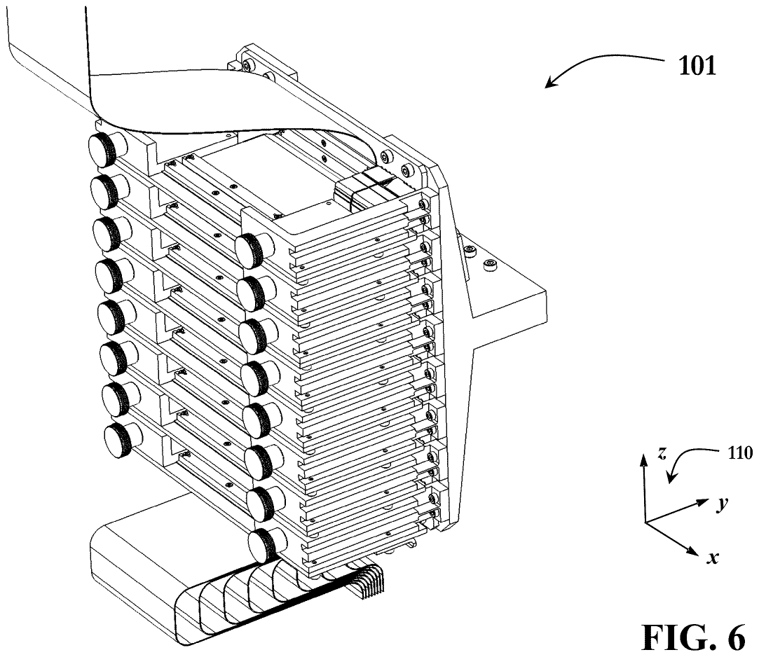

FIG. 5 illustrates an artificially exploded view of CCA 101. CCA 101 is further illustrated by FIG. 6, which is a perspective view of CCA 101 when assembled. CCA 101 can comprise a backplane assembly 102, a cold-plate assembly 104, and an array 106 of field-replaceable unit (FRU) assemblies 108.n, where n is an integer index ranging from 1 to N.

All figures herein illustrate the case N=8, with array 106 being arrayed along a z axis of an imaginary Cartesian coordinate system 110, which comprises mutually orthogonal axes x, y, and z.

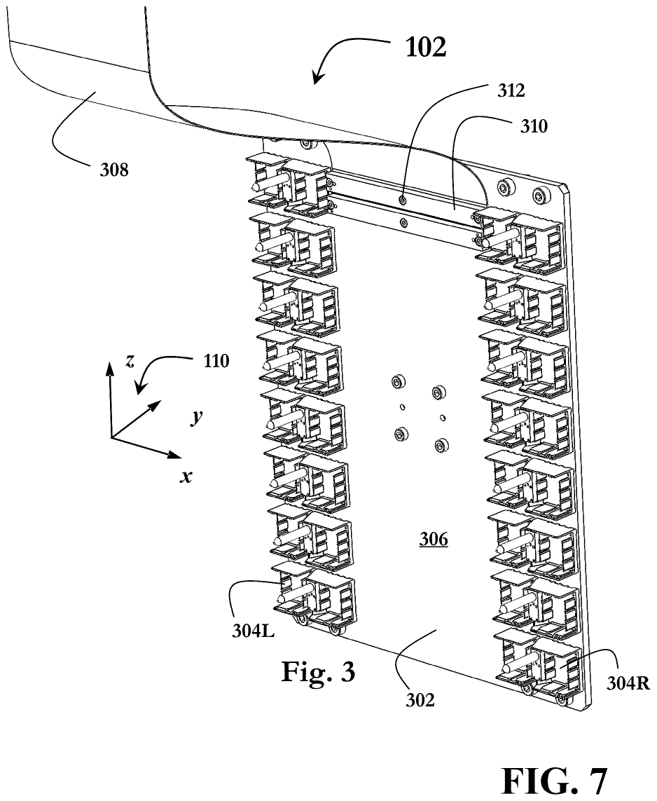

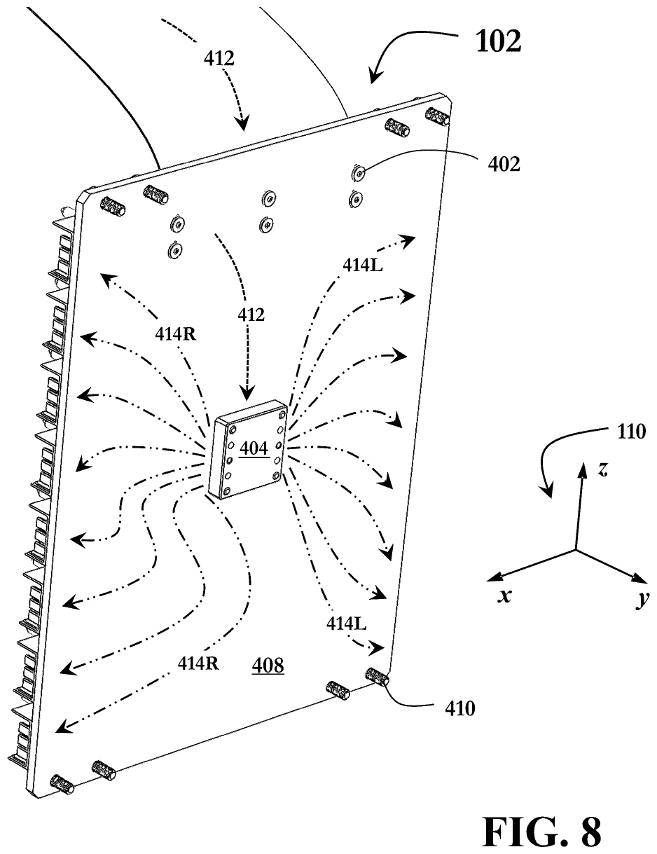

FIG. 7 and FIG. 8 are front and rear views, respectively, that illustrate backplane assembly 102. Backplane assembly 102 can comprise backplane 302, where backplane 302 is a printed-circuit-board; a left array of backplane connectors 304L that can be electrically connected to a front surface 306 of backplane 302; a right array of backplane connectors 304R connected likewise; input cable 308; at least one input connector 310 that can electrically connect input cable 308 to backplane 302, and can be secured to front surface 306 by fasteners 312 and fasteners 402; a hub-chip assembly 404 that can comprise hub-chip 406 (embedded in hub-chip assembly 404, but not visible in the figures), where hub-chip 406 can be silicon and can be electrically connected to a rear surface 408 of backplane 302; and a plurality of cold-plate-to-backplane fasteners 410. A plurality of backplane input signals 412 (e.g., a plurality of RTE signals), carried on input cable 308, can be electrically connected to conductors in backplane 302 by input connectors 310, and can be carried thence to hub-chip 406 of hub-chip assembly 404, which can create therefrom an array of FRU-specific left-input signals 414L and right-input signals 414R that can be distributed in backplane 302 to backplane connectors 304L and 3204R, respectively, and thereby to array 106 of FRU assemblies 108.n.

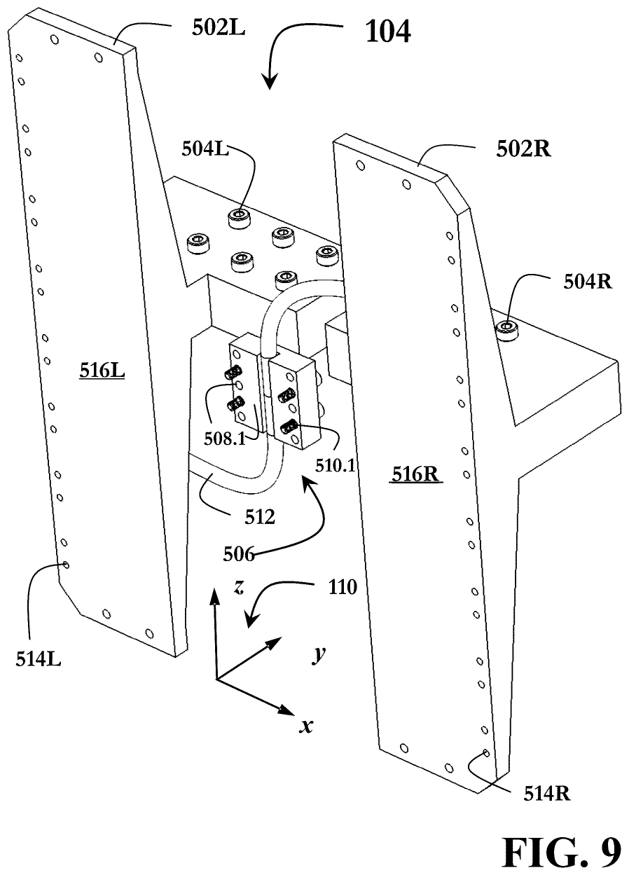

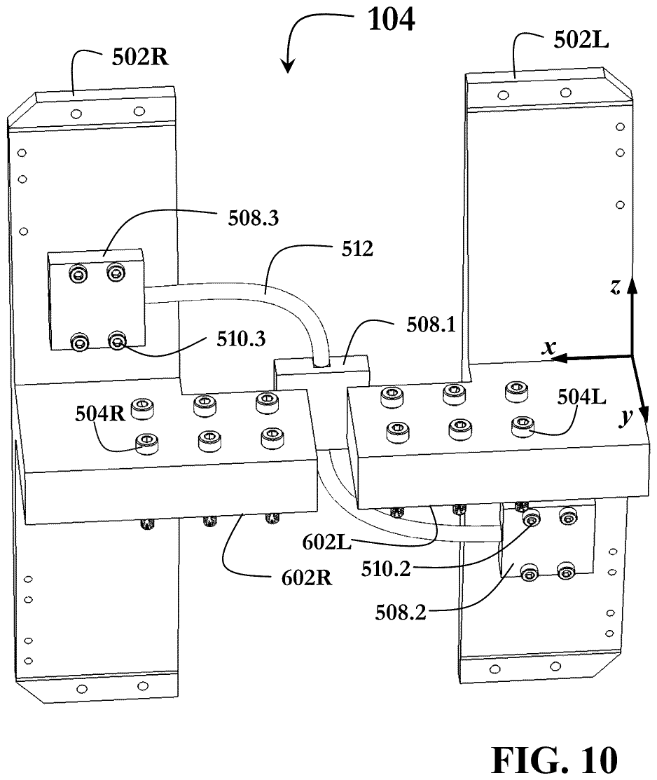

FIG. 9 and FIG. 10 are front and rear views, respectively, that illustrate cold-plate assembly 104, which can comprise a left cold-plate 502L; a right cold-plate 502R; a first array of fasteners 504L that mechanically affix a lower surface 602L of left cold-plate 502L to a refrigerated plate not shown (e.g., cooling plate 318) that is cooled to first cryogenic temperature T₁ (for example, T₁=10K), such that lower surface 602L of left cold-plate 502L is held at temperature T₁; a second array of fasteners 504R that mechanically affix a lower surface 602R of right cold-plate 502R to said refrigerated plate, such that lower surface 602R of right cold-plate 502R is held at temperature T₁; and a heat-sink assembly 506 for hub-chip assembly 404. Heat-sink assembly 506 can comprise a first cold-block 508.1 affixed to hub-chip assembly 404 with fasteners 510.1; a second cold-block 508.2 affixed to left cold-plate 502L with fasteners 510.2; a third cold-block 508.3 affixed to right cold-plate 502R with fasteners 510.3; and a flexible, conductive rope 512 made, for example, of high-thermal-conductivity braided copper, which is thermally affixed (e.g., by solder) to cold-blocks 508.1, 508.2, and 508.3, and which thereby conveys heat from hub-chip assembly 404 to cold plates 502L and 502R, and thence to said refrigerated plate.

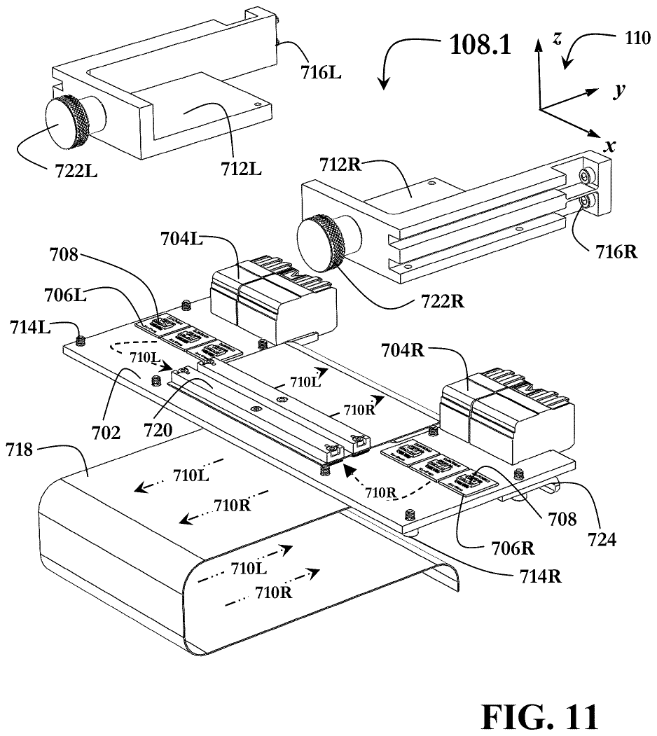

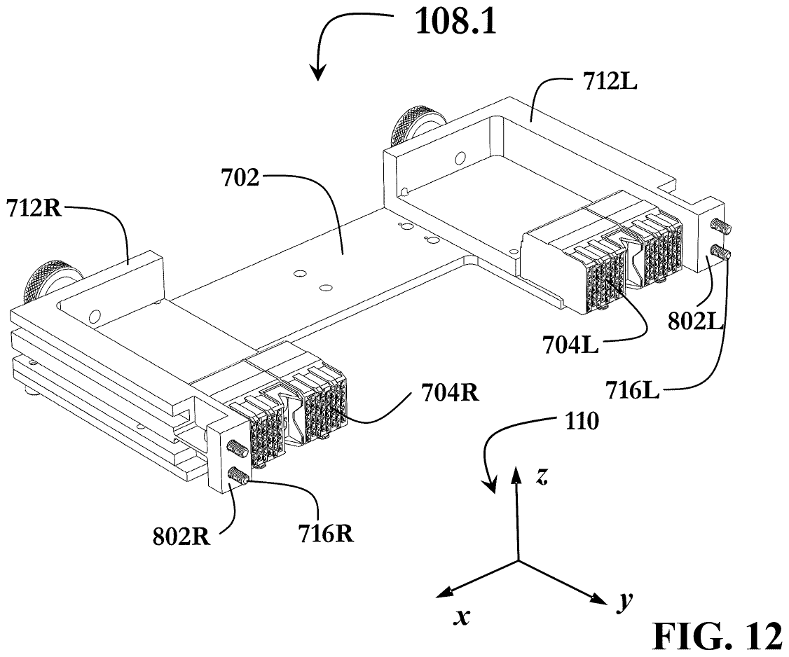

FIG. 11 and FIG. 12 illustrate FRU 108.1: FIG. 11 illustrates an exploded view of all elements of FRU 108.1; FIG. 12 illustrates an assembled view of FRU 108.1 with several elements hidden. All of FRU assemblies 108.n (n=1, . . . , 8) are similar; the slight differences are shown subsequently. Referring to FIG. 11 and FIG. 12, FRU 108.1 can comprise a printed-circuit-board daughter card 702 that is U-shaped; a left array of daughter-card connectors 704L (e.g., a left array of receptacles) that can engage left array of backplane connectors 304L and thereby can convey left input signals 414L to daughter card 702; and a right array of daughter-card connectors 704R (e.g., a right array of receptacles) that can engage right array of backplane connectors 304R and thereby can convey right input signals 414R to daughter card 702.

The U-shaped daughter card 702 can consist of a base and two legs (a left leg and a right leg), where there is an open area between the two legs. The left array of daughter-card connectors 704L can be electrically connected to a distal end of the left leg, and the right array of daughter-card connectors 704R can be electrically connected to a distal end of the right leg.

FRU 108.1 can further comprise a left, m-fold array of daughter-card chip assemblies 706L (shown with m=3), each comprising a daughter-card chip 708, that together can receive left input signals 414L and can produce an array of left output signals 710L; and a right, m-fold array of daughter-card chip assemblies 706R (shown with m=3), each comprising an instance of daughter-card chip 708, that together can receive right input signals 414R and can produce an array of right output signals 710R; a left, high-thermal-conductivity heat spreader 712L that can be mechanically affixed to daughter card 702 with a plurality of fasteners 714L, can be mechanically affixed to left cold-plate 502L with a plurality of fasteners 716L (e.g., screws), and is thermally in contact with daughter-card chips 708 of left daughter-card chip assemblies 706L, thereby to allow heat generated by daughter-card chips 708 of left daughter-card chip assemblies 706L to be transmitted to left cold-plate 502L and thence to the refrigerated plate; and a right, high-thermal-conductivity heat spreader 712R that is mechanically affixed to daughter card 702 with a plurality of fasteners 714R, is mechanically affixed to right cold-plate 502R with a plurality of fasteners 716R (e.g., screws), and is thermally in contact with daughter-card chips 708 of right daughter-card chip assemblies 706R, thereby to allow heat generated by daughter-card chips 708 of right daughter-card chip assemblies 706R to be transmitted to right cold-plate 502R and thence to the refrigerated plate. The daughter-card chips 708 can be electrically connected to a proximal end of each of the two legs of U-shaped daughter card 702.

FRU 108.1 can further comprise output cable 718 (hidden in FIG. 12) that, at its proximal end, is electrically connected and removably affixed to daughter card 702, at the base, using at least one connector 720 (hidden in FIG. 12), thereby to convey output signals 710L and 710R to output cable 718, and thereby to allow output signals 710L and 710R to be conveyed to equipment (not shown) that is connected to output cable 718 at its distal end (not shown); and handle 722L and 722R that is mechanically affixed to each heat spreader 712L and 712R, respectively, thereby to assist with the disconnection of daughter-card connectors 704L and 704R from backplane connectors 304L and 304R by providing places to grasp FRU 108.1 when manual force is applied thereto in the-y direction for the purpose of removing FRU 108.1 for repair or replacement.

Although daughter card 702 is primarily discussed herein as comprising a U-shape, note that daughter card 702 can comprise any suitable shape. For example, daughter card 702 can be rectangular, wherein daughter-card chips 708 can be electrically connected to a proximal end of each of the two legs, and wherein output cable 718 extends off a front of the daughter-card chip assemblies 706 (e.g., in the +x direction). In such case, the array 106 of FRUs 108 will result in a layered set of output cables 718, wherein a top FRU in array 106 can be removed independently from other FRUs in array 106.

Referring to FIG. 11, FIG. 12, and FIG. 9, a heat load generated by daughter-card chips 708 can be conducted to heat spreaders 712L and 712R by interposing between each daughter-card chip 708 and heat spreader 712 a pad composed of compliant, high-thermal-conductivity material such as indium. Said heat load can then be conducted through heat spreaders 712L and 712R, composed of high-thermal-conductivity material such as oxygen-free copper, to interfacial surfaces 802L and 802R, respectively, which, by virtue of fasteners 716L and 716R that engage holes 514L and 514R (FIG. 9), can be in intimate contact with surfaces 516L and 516R of cold plates 502L and 502R, respectively, which can also be composed of high-thermal-conductivity material such as oxygen-free copper. Said heat load can then be conducted through cold plates 502L and 502R to bottom surfaces 602L and 602R thereof, and thence to said refrigerated plate (not shown) that is in intimate thermal contact with bottom surfaces 602L and 602R by virtue of fasteners 504L and 504R, respectively.

Referring to FIG. 11, FRU 108.1 can further comprise a mandrel 724 (hidden in FIG. 12) that is mechanically attached to daughter card 702 using a subset of fasteners 714L and 714R. Mandrel 724, whose purpose is described later, can be absent for other FRUs 108.2, 108.3, . . . , 108.n.

Now referring to FIG. 6, FIG. 10, and FIG. 11, one objective of CCA 101 is to reduce, as much as possible, cryogenic thermal resistance against heat flow from daughter-card chips 708 to said refrigerated plate that abuts cold-plate surfaces 602L and 602R, thereby to minimize the temperature rise from said refrigerated plate to daughter-card chips 708. Toward this objective, there can be two strategies in the design of CCA 101. Firstly, the design can have just three thermal interfaces in the heat-flow path from daughter-card chips 708 to said refrigerated plate: first, from daughter-card chip 708 to heat spreader 712L or 712R; second, from heat spreader 712L or 712R to cold-plate 502L or 512 R, and third, from cold-plate 502L or 512R to said refrigerated plate. Secondly, the heat-conducting elements—including heat spreaders (712L, 712R) and cold-plates (502L, 502R)—can be composed, as previously mentioned, of a material having high cryogenic thermal conductivity, such as oxygen-free copper.

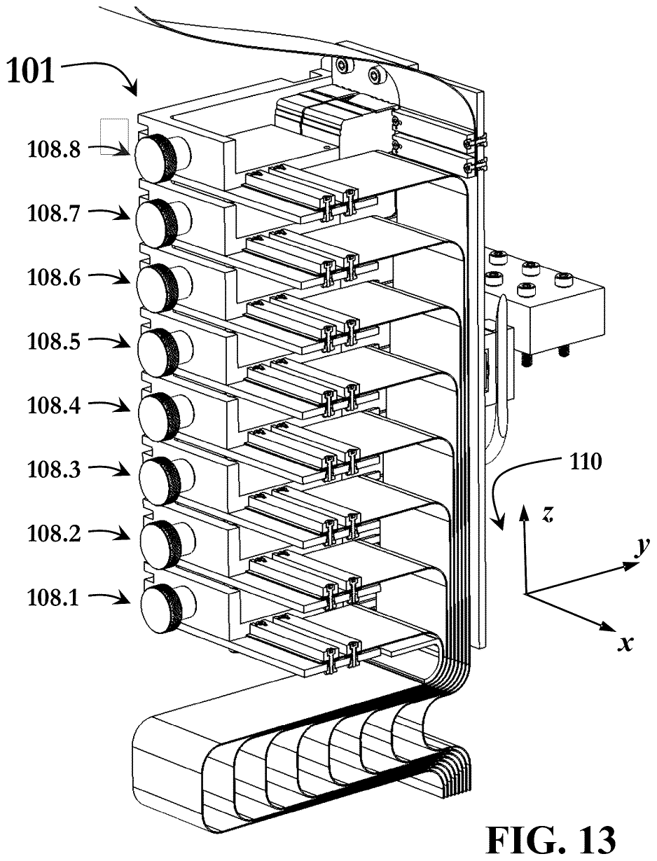

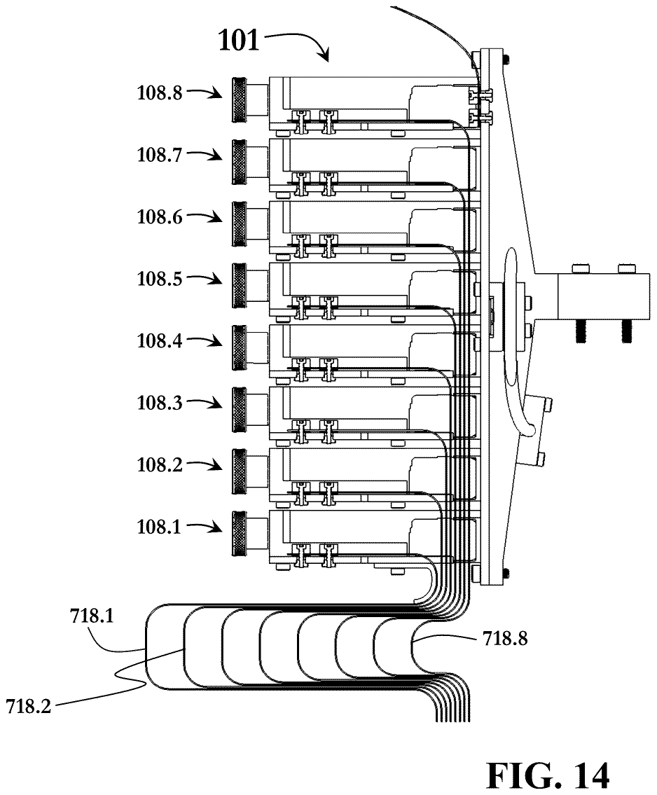

FIG. 13 and FIG. 14 are cutaway renderings of CCA 101. FIG. 13 is a perspective view thereof, whereas FIG. 14 is a side view thereof. These figures clarify the arrangement of output cables 718.1 through 718.8 that connect to FRUs 108.1 through 108.8, respectively.

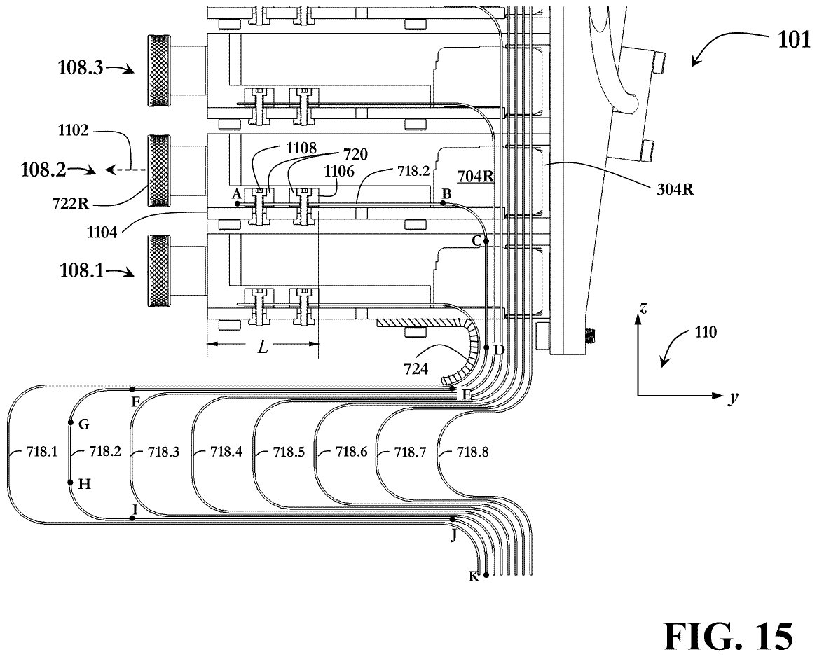

Referring to FIG. 15, which is a magnified view of a lower portion of FIG. 14, suppose that FRU 108.2 needs to be removed for repair or replacement. In FIG. 15, output cable 718.2 is annotated by imaginary points A through K, wherein portion FGHI of the cable comprises a “service loop”. To remove FRU 108.2, fasteners 716R and 716L (FIG. 11) that affix FRU 108.2 to cold plates 502L and 502R (FIG. 9) can be first removed. FRU 108.2 can then be removed by grasping handles 722L and 722R and pulling in the −y direction to disconnect daughter-card connectors 704L and 704R from backplane connectors 304L and, 304R, as indicated by imaginary arrow 1102. This action causes segment ABC of output cable 718.2 to move leftward on FIG. 15, but point D is restricted against leftward movement by mandrel 724. Consequently, point D of cable 108.2 can begin to slide upward around mandrel 724, causing service loop FGHI of output cable 718.2 to approach output cable 718.3. The geometry can be arranged so that the arc length of service loop FGHI is greater than a distance L from daughter-card edge 1104 to connector edge 1106, and thus is sufficient to allow connectors 720 to emerge from underneath the footprint of FRUs above, and thus to allow easy removal of fasteners 1108 from connectors 720, thereby freeing daughter card 702 from output cable 718.2, and allowing removal of all of FRU 108.2 except its output cable 718.2. Such a removal scenario can be performed likewise for any of the other FRUs. Thus, any FRUs in array 106 can be removed without removing other FRUs in array 106, and without removing an of the set of output cables 718.

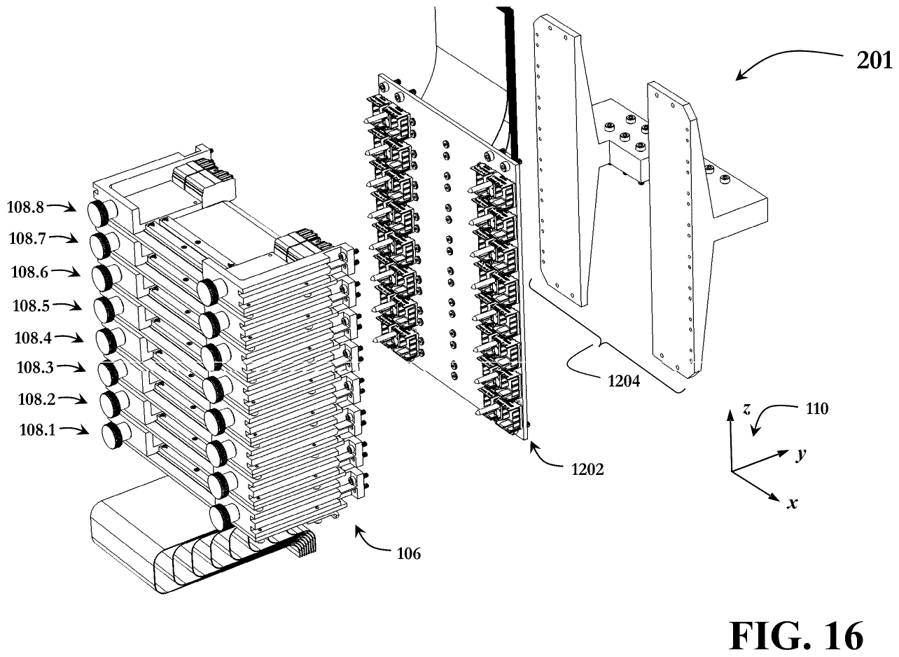

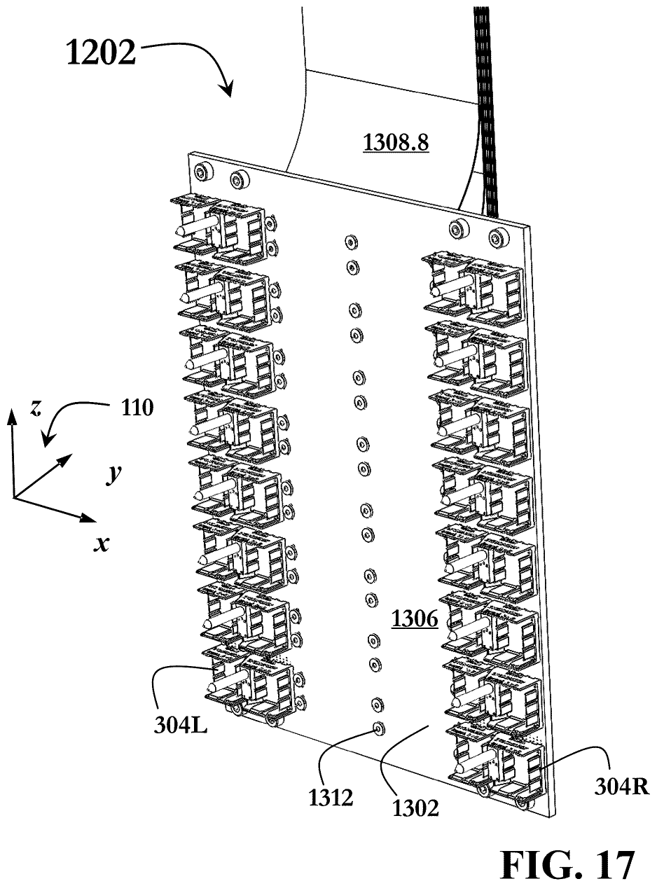

FIG. 16 is an exploded diagram that illustrates CCA 201 of second embodiment 200, which can comprise a backplane assembly 1202, a cold-plate assembly 1204, and—as in CCA 101 of first embodiment 100—array 106 of field-replaceable unit (FRU) assemblies 108.n, where n is an integer index ranging from 1 to N. Because array 106 in FIG. 17 is identical to array 106 in FIG. 5, only backplane assembly 1202 and cold-plate assembly 1204 need be explicated for CCA 201 of second embodiment 200.

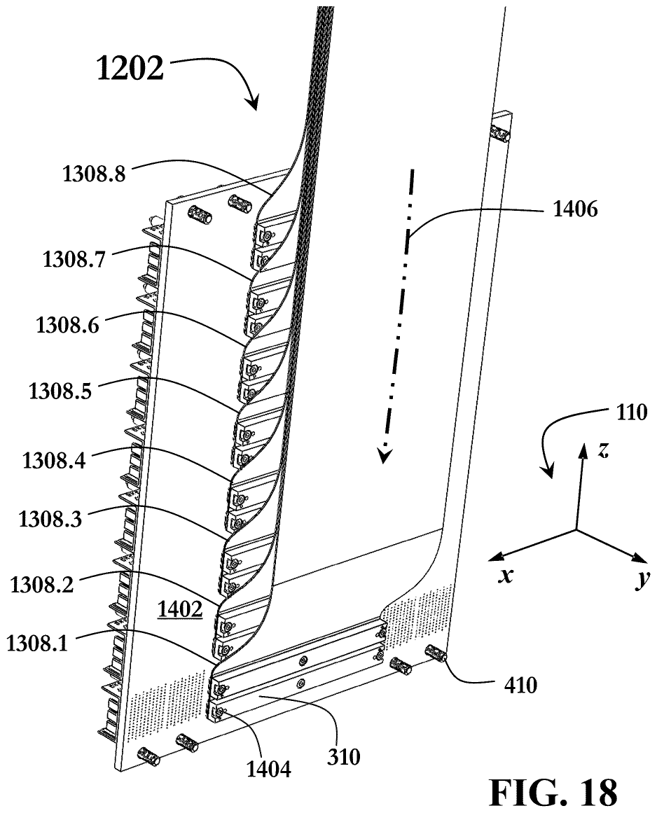

FIG. 17 and FIG. 18 are front and rear views, respectively, that illustrate backplane assembly 1202, which can comprise backplane 1302, where backplane 1302 is a printed-circuit-board; a left array of backplane connectors 304L that can be electrically connected to a front surface 1306 of backplane 1302; a right array of backplane connectors 304R connected likewise; an array of input cables 1308.1 through 1308.8, each input cable 1308 terminated in at least one input connector 310 that can electrically connect input cable 1308 to a rear surface 1402 of backplane 1302, and can be secured to rear surface 1402 by fasteners 1312 and 1404; and a plurality of cold-plate-to-backplane fasteners 410. A plurality of backplane input signals 1406, carried on each input cable 1308, can be electrically connected to conductors in backplane 1302 by input connectors 310, and can be carried thence to backplane connectors 304L and 304R, and thereby to array 106 of FRU assemblies 108.n.

That is, backplane assembly 1202 of CCA 201 differs from backplane assembly 102 of CCA 101 in that backplane assembly 102 comprises hub-chip assembly 404 and associated electrical wiring to provide backplane input signals 412, input signals 414L and input signals 414R, whereas backplane assembly 1202 comprises array of input cables 1308.1 through 1308.8, associated input connectors 310, fasteners 1312 and 1404, and associated electrical wiring to provide signals from array of input cables 1308.1, . . . , 1308.8 to backplane connectors 304L and 304R.

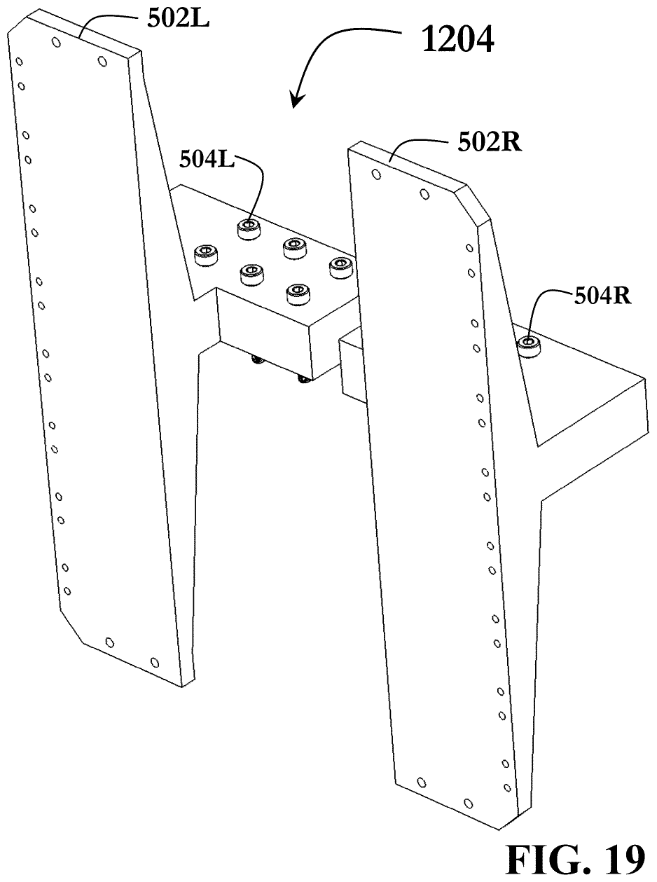

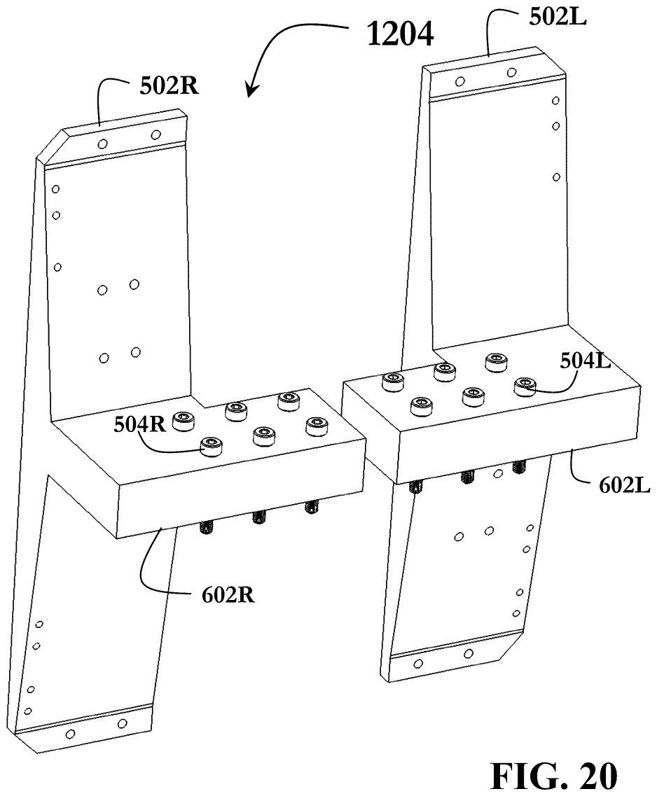

FIG. 19 and FIG. 20 are front and rear views, respectively, that illustrate cold-plate assembly 1204, which can comprise left cold-plate 502L; right cold-plate 502R; first array of fasteners 504L that mechanically affix left cold-plate 502L with low thermal resistance to said refrigerated plate (not shown) held at cryogenic temperature T₁ (for example, T₁=10K), such that lower surface 602L of left cold-plate 502L is held at temperature T₁; second array of fasteners 504R that mechanically affix right cold-plate 502R with low thermal resistance to said refrigerated plate, such that lower surface 602R of right cold-plate 502R is held at temperature T₁.

That is, cold-plate assembly 1204 of CCA 201 can be identical to cold-plate assembly 504 of CCA 101 except that cold-plate assembly 1204 does not comprise heat-sink assembly 506. The latter is not necessary for cold-plate assembly 1204 because CCA 201 does not comprise hub-chip assembly 404.

Because CCA 201 of second embodiment 200 can be, except for handling of input signals, the same as CCA 101 of first embodiment 100, neither the foregoing explanation of FRU removal nor the explanation of heat flow from daughter-card chips 708, previously given for CCA 101 of first embodiment 100, need be repeated for CCA 201 of second embodiment 200.

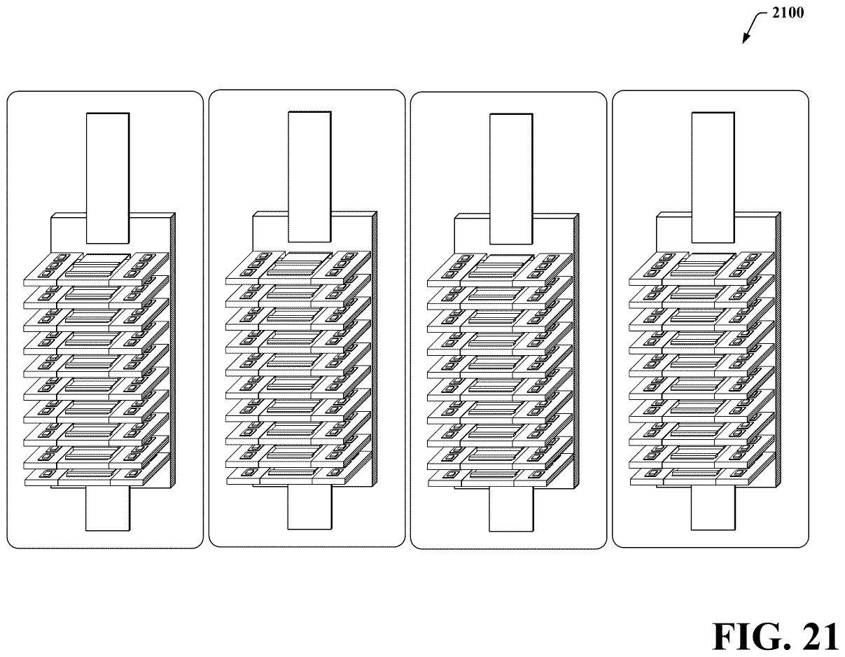

FIG. 21 illustrates an array 2100 of fully populated cryogenic control packages, each containing a set of FRUs designed to manage 1000 qubits worth of flux control. The high-density packaging infrastructure of CMOS ASICs provided by first embodiment 100 and second embodiment 200 can allow for modular replacement and maintenance of components within the system, ensuring the system remains operational over time, while improving scalability to larger quantum systems within the limited physical space of a dilution refrigerator by housing a significant number of CMOS ASICs. That is, as the size of the quantum processor increases, more control electronics are needed to be able to control those numbers of qubits while adhering to the thermal and spatial limitations within the dilution refrigerator. The high-density packaging infrastructure of CMOS ASICs provided by CCA 101 and CCA 201 can adhere to such thermal and special limitations while providing enough control electronics as the size of the quantum processor increases.

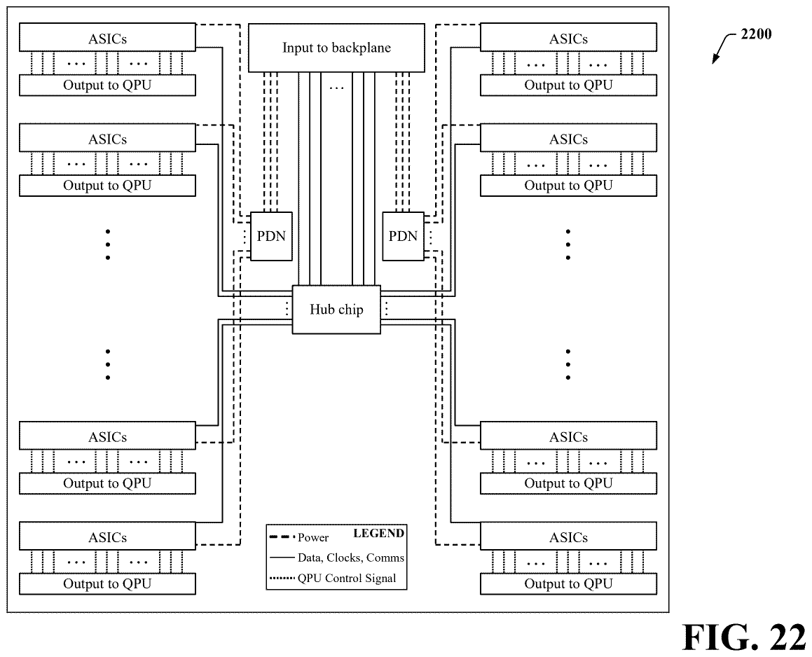

FIG. 22 illustrates a block diagram 2200 of wiring of CCA 101 of first embodiment 100 in accordance with one or more embodiments described herein.

The hub-chip 406 of CCA 101 can result in an active backplane 302 and multiplex the ASIC input signals (e.g., set of input signals 414), such as clocks, data, communications, or power, to the array of ASICs 706. In various aspects, hub-chip 406 can significantly reduce the number of signal lines required to go into the dilution refrigerator. The ASIC input signals can be delivered into backplane 302 from RTE 112. In various cases, the ASIC input signals can be routed through hub-chip 406 or can be routed through a power distribution network (PDN), which is a wiring arrangement for multiplexing supply lines. The backplane connectors 304 are used to plug in the set of CCUs 108 to backplane 302. Thereafter, the ASIC input signals are delivered through backplane connectors 304. Power domains can be distributed to the array of ASICs through a PDN, which can provide sufficient decoupling capacitance to minimize supply ripple (e.g., the residual periodic variation or noise present on the power supply voltage). Then, the array of ASICs 706 can generate QPU control signals (e.g., set of output signals) that escape CCA 101 and launch into the set of output cables 718 that traverses other stages of the dilution refrigerator. That is, the QPU control signals can be conveyed to QPU 114 at the bottom of the dilution refrigerator. In various embodiments, the set of output cables 718 can be high-density ribbon cables.

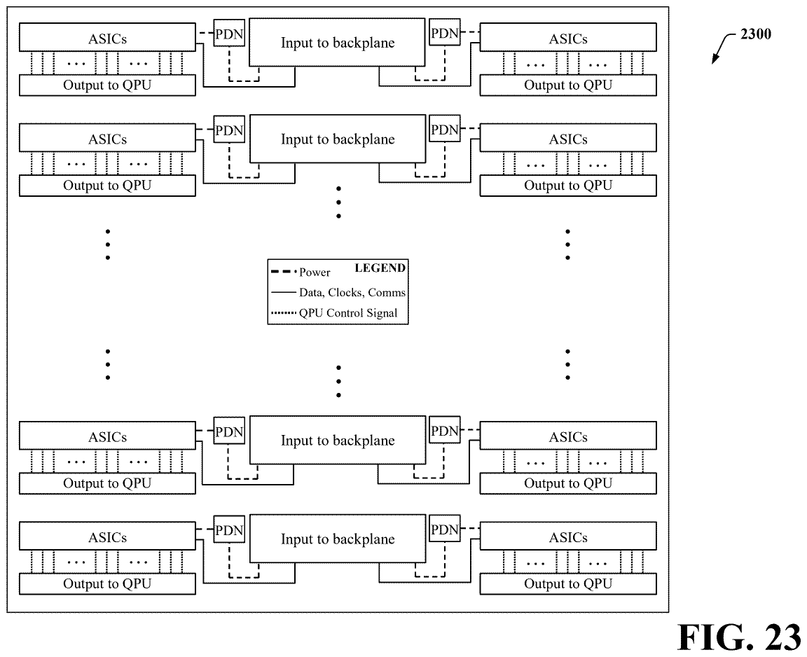

FIG. 23 illustrates a block diagram 2300 of wiring of CCA 201 of second embodiment 200 in accordance with one or more embodiments described herein.

Absence of hub-chip 406 will result in a passive backplane 302, which can be easier to develop or build. In some cases, the passive backplane 302 may cause additional wiring complexity. Therefore, hub-chip 406, as in CCA 101, can reduce wiring complexity and therefore decrease packaging size.

In CCA 201, the ASIC input signals (e.g., set of input signals 414) can be delivered from room-temperature electronics (e.g., RTE 112). Then, ASIC input signals can be routed through PDNs. Specifically, each ASIC input signal can be routed through a PDN to each ASIC. In various aspects, each input cable of the set of input cables 308 can support a CCU of the set of CCUs 108. Similarly to CCA 101, backplane connectors 304 are used to plug in the set of CCUs 108 to backplane 302. Thereafter, the ASIC input signals are delivered through backplane connectors 304. Then, the array of ASICs 706 can generate QPU control signals (e.g., set of output signals) that escape CCA 201 and launch into the set of output cables 718 that traverses other stages of the dilution refrigerator to be conveyed to QPU 114.

Embodiments of the present invention may be a system, a method, and/or an apparatus at any possible technical detail level of integration. What has been described above includes mere examples of systems, methods, and apparatus. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings, such terms are intended to be inclusive in a manner similar to the term “comprising” as “comprising” is interpreted when employed as a transitional word in a claim.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain example embodiments have been described, these embodiments have been presented by way of example only, and are not intended to limit the scope the disclosures herein. Thus, nothing in the foregoing description is intended to imply that any particular feature, characteristic, step, module, or block is necessary or indispensable. Indeed, the novel methods and systems described herein may be embodied in a variety of other forms; furthermore, various omissions, substitutions and changes in the form of the methods and systems described herein may be made without departing from the spirit of the disclosures herein. The accompanying claims and their equivalents are intended to cover such forms or modifications as would fall within the scope and spirit of certain of the disclosures herein.

What is claimed is:

1. A structure, comprising:
a backplane assembly, comprising:
an internal backplane wiring that conveys, via a hub chip, a set of input signals from an input cable to a set of backplane connectors; and
a set of daughter-card assemblies, comprising:
a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

2. The structure of claim 1, wherein one or more of the set of daughter-card assemblies comprise:
a heat-spreader that is in thermal contact with the set of processing chips and with a high-thermal-conductivity backplate, and wherein the high-thermal-conductivity backplate is in thermal contact with a refrigerated plate that is held at the first cryogenic temperature.

3. The structure of claim 1, wherein each of the set of daughter-card assemblies comprise:
a daughter card that is a U-shape, wherein the daughter card comprises a base and two legs.

4. The structure of claim 3, wherein the set of daughter-card assemblies comprise:
a set of receptacles for electrical connection to a subset of the set of backplane connectors, wherein the set of receptacles are electrically connected to a distal end of each of the two legs, wherein the set of processing chips are electrically connected to a proximal end of each of the two legs, and wherein the set of output cables are electrically connected to the set of quantum processors at the second cryogenic temperature.

5. The structure of claim 4, wherein the set of output cables are routed through an open area of the U-shape such that any of the set of daughter-card assemblies are capable of being separately removed without removing any other of the set of daughter-card assemblies, and such that any of the set of daughter-card assemblies are capable of being separately removed without removing any of the set of output cables.

6. The structure of claim 1, wherein each of the set of daughter-card assemblies comprises a daughter card that is rectangular, wherein the set of output cables extend off a front of the set of daughter-card assemblies, and wherein a top daughter-card assembly of the set of daughter-card assemblies is capable of being independently removed.

7. The structure of claim 2, further comprising:
a cold plate assembly, comprising:
a left cold plate and a right cold plate that affix to the refrigerated plate.

8. The structure of claim 7, further comprising:
a heat sink assembly, comprising:
a first cold block that is affixed to the hub chip;
a second cold block that is affixed to the left cold plate; and
a third cold block that is affixed to the right cold plate, wherein the first cold block, the second cold block, and the third cold block are connected by a thermally affixed conductive rope.

9. The structure of claim 2, wherein the heat-spreader comprises a set of handles.

10. A structure, comprising:
a backplane assembly, comprising:
an internal backplane wiring that separately conveys a set of input signals from a set of input cables to a set of backplane connectors; and
a set of daughter-card assemblies, comprising:
a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

11. The structure of claim 10, wherein one or more of the set of daughter-card assemblies comprise:
a heat-spreader that is in thermal contact with the set of processing chips and with a high-thermal-conductivity backplate, and wherein the high-thermal-conductivity backplate is in thermal contact with a refrigerated plate that is held at the first cryogenic temperature.

12. The structure of claim 10, wherein each of the set of daughter-card assemblies comprise:
a daughter card that is a U-shape, wherein the daughter card comprises a base and two legs.

13. The structure of claim 12, wherein the set of daughter-card assemblies comprise:
a set of receptacles for electrical connection to a subset of the set of backplane connectors, wherein the set of receptacles are electrically connected to a distal end of each of the two legs, wherein the set of processing chips are electrically connected to a proximal end of each of the two legs, and wherein the set of output cables are electrically connected to the base.

14. The structure of claim 13, wherein the set of output cables are routed through an open area of the U-shape such that any of the set of daughter-card assemblies are capable of being separately removed without removing any other of the set of daughter-card assemblies, and such that any of the set of daughter-card assemblies are capable of being separately removed without removing any of the set of output cables.

15. The structure of claim 11, further comprising:
a cold plate assembly, comprising:
a left cold plate and a right cold plate that affix to the refrigerated plate.

16. A structure, comprising:
a cryogenic control assembly (CCA) that is positioned inside a dilution refrigerator, wherein the CCA is thermally anchored to a second stage of a pulse tube, or to a liquid helium circulation circuit, and wherein the CCA comprises:
a backplane assembly that conveys a set of input signals from one or more input cables to a set of backplane connectors; and
a set of cryogenic control units (CCUs), comprising:
a set of processing chips that are electrically connected to the set of backplane connectors and to a set of output cables, wherein the set of processing chips generate, at a first cryogenic temperature, a set of output signals as functions of the set of input signals, and wherein the set of output signals are conveyed, via the set of output cables, to a set of quantum processors at a second cryogenic temperature.

17. The structure of claim 16, further comprising:
a hub chip assembly that multiplexes the set of input signals to the set of CCUs.

18. The structure of claim 16, wherein the set of CCUs are thermally anchored to the second stage of the pulse tube or to the liquid helium circulation circuit.

19. The structure of claim 16, wherein the one or more input cables are high-density ribbon cables.

20. The structure in claim 16, wherein the set of processing chips form multi-chip modules on a daughter card.
